(19) United States
(12) Patent Application Publication
(10) Pub. No.: US 2016/0126895 A1
(43) Pub. Date: May 5, 2016

(54) SWITCHED MODE POWER AMPLIFIER WITH IDEAL IQ COMBINING

(71) Applicant: Texas Instruments Incorporated, Dallas, TX (US)

(72) Inventors: Gireesh Rajendran, Bangalore (IN); Rakesh Kumar, Uttar Pradesh (IN); Alok Prakask Joshi, Maharastra (IN); Subhashish Mukherjee, Bangalore (IN); Krishnaswamy Thiagarajan, Bangalore (IN); Apu Sivadas, Bangalore (IN)

(21) Appl. No.: 14/529,056

(22) Filed: Oct. 30, 2014

(51) Int. Cl. H03F 1/02; H03F 3/19; H04L 27/34; H03F 3/217

(52) U.S. Cl. CPC H03F 1/0205; H03F 3/217; H03F 3/19; H04L 27/3405; H03F 2200/451; H03F 2200/336

(57) ABSTRACT

An I converter outputs I sign data and I magnitude data based on received I data. A Q converter outputs Q sign data and Q magnitude data based on received Q data. An I clock generates an I phase based ort the I sign data. A Q clock generates a Q phase based on the Q sign data. An I modulator generates an I magnitude pulse stream based on the I magnitude data. A Q modulator generates a Q magnitude pulse stream based on the Q magnitude data. A digital logic component generates an output signal based on the I phase, the I magnitude pulse stream, the Q phase and the Q magnitude pulse stream. A power amplifier generates an amplified signal based on the output signal.

### BACKGROUND

The present invention relates generally to power amplifiers and deals more particularly with wireless transmitter structures having switching mode power amplifiers.

Wireless applications have grown quickly to become significant markets due to the advancements in wireless devices. The advance in low-cost complementary metal-oxide-semiconductor (CMOS) technology has made it a natural choice for radio frequency (RF) transceivers in wireless applications. Its progress has enabled the integration of baseband and other functional blocks. CMOS technology will, be the most feasible solution, for full integration on a single die, reducing package form factors and their costs. In addition, CMOS technology provides good thermal characteristics and a low-cost advantage owing to its matured process technology as well as a high level of integration. In power amplifiers (PAs), the performance issues are output power, efficiency, linearity, gain, and reliability. In constant envelope systems, such as global systems for mobile communications (GSM), the demand of high-efficiency performance has been a priority to extend battery lifetime. For highly efficient operation, nonlinear switching PAs are attractive due to their high DC-to-RF conversion efficiency. High efficiency improves the operation time and reliability of radio frequency (RF) transceivers and is one of the most important requirements of PAs for wireless applications.

The use of high efficiency of nonlinear switching CMOS PAs in GSM applications relies partly on the transmitter propagating phase content only, i.e. there is no amplitude content to propagate. Switching PAs are efficient because they drive usually only two states (although multilevel switching PAs exist, too) at the output, the two states representing zero or full supply voltage (V_{DD}). However, it is highly desirable that such PAs can be used efficiently for analog in-phase and quadrature (I and Q) input data in which both phase and amplitude content exists. Currently, there are a few techniques for the design of these applications, these techniques typically involving different methods of combining I and Q phase and amplitude data into data streams which can directly modulate the switch-mode PA. These techniques have drawbacks, however. One such approach to be described involves changing both the amplitude and phase content into a single data stream by first converting IQ data to polar data and then converting the polar data to a single-bit delta-sigma stream. The operation is explained using FIG. 1.

FIG. 1 shows a conventional system 106 for converting analog IQ data for modulating a CMOS switching PA.

System 100 includes a converter 102, a delta-sigma modulator 164, a polar amplitude component 106, a power component 107, a polar phase component 108 and a PA 110.

As shown in the figure, converter 102 is arranged to receive on a line 112 and a line 114 and output on a line 116, a line 117 and a line 118. Delta-sigma modulator 104 is arranged to connect between polar converter 102 via line 118 and polar amplitude component 106 via a line 120. Polar amplitude component 106 then connects to PA 110 via a line 124. Polar phase component 108 is arranged to connect to converter 102 via line 116 and line 117 and to connect to PA 110 via a line 122. Power control component 107 interfaces with polar amplitude component 106 via a line 121. PA 110 outputs signals on a line 126.

Converter 102 provides the sampling and filtering functions necessary to convert Cartesian data to polar data. Delta-sigma modulator 104 digitizes analog polar amplitude data into a single bit stream. Polar amplitude component 106 converts a bit stream to a signal, for modulating the supply voltage of PA 110, polar phase component 108 provides digitization and conversion for the digitized data to drive PA 110.

In operation, converter 102 converts the analog I and Q which is in Cartesian x, y coordinate form into polar coordinate form as r (amplitude) and Θ (angle). Amplitude information, appearing on line 118, is digitized using delta-sigma conversion by delta-sigma modulator 104. The data stream produced, and appearing on line 120, is then conditioned by polar amplitude component 106 and the output, on line 124, modulates the supply to PA 110 by either changing the DC bias at PA 110 or by directly changing the supply voltage. Amplitude information is therefore coded using the supply voltage to the power amplifier, PA 110. Polar phase (angle) information appears as a Θ signal on line 116. These signals are then digitized and conditioned by polar phase component 122 to drive the power amplifier, PA 110. Thus, analog I and Q amplitude information containing both amplitude and phase information is used with a CMOS switch-mode PA by using Cartesian to Polar conversion in conjunction with delta-sigma modulation.

This system has some inherent problems, however. One problem occurs due to the IQ data to polar conversion process. Since the Cartesian to polar phase angle part of this conversion process is non-linear (polar angle=tan⁻¹ (y/x)), this process significantly widens the bandwidth, occupied by the output signal. This leads to the requirement for much, larger channel widths, or can lead to adjacent channel performance problems. Another problem is that the performance is restricted since the supply voltage bandwidth is low. Consequently, while lower bandwidth data applications such as Bluetooth may be supported, high bandwidth data applications such as WiFi cannot.

A second conventional system and method to convert analog IQ data, for modulating a CMOS switching PA is described in “Method and apparatus for a fully digital quadrature modulator” Oreo E. Eliezer, U.S. Pat. No. 7,460,612. This system and method combines I and Q data through the use of 11-bit I and Q control words applied to switch arrays which drive a multilevel PA operating at four levels representing I+Q, I−Q; −(I−Q) and −(I+Q). This system and method leads to an elaborate and complex implementation which can have problems.

The first problem is that implementation requires using a multilevel PA, even if I and Q are independently realized with a single level. The second problem is I to Q leakage manifesting as data corruption. The leakage is due to insufficient PA settling time being available for the large data magnitude excursions possible, said excursions being as large as from zero to (I+Q) is a ¼) local oscillator (LO) period.

What is needed is a system and method for combining the information in analog I and Q inputs to realize a highly efficient CMOS switching PA which is not subject to the large bandwidth requirements and phase modulation driven performance limitations of the first example conventional system and which does not have the multilevel PA requirement or the I to Q leakage driven data corruption problems of the second example conventional system.

### BRIEF SUMMARY

The present invention provides a novel system and method for combining I and Q analog inputs to realize a highly efficient CMOS switching PA which is not subject to the large bandwidth requirements, phase modulation driven performance limitations and the I to Q leakage and data corruption problems of conventional systems.

Aspects of the present invention are drawn to provision of converters to convert analog data streams I and Q into separate magnitude and sign data; a local oscillator (LO) to generate a clock with period T; pulse generators to provide poises used to gate amplitude data based on sign data: delta-signal modulators to generate bit streams based on analog magnitude data; digital logic to output a single data stream representing the combined I and Q data and derived from the gated magnitude data with sign information determining position in the LO cycle; a PA to generate an amplified signal based on the output signal such that the Q data appears out of phase from the I data.

Other aspects of the invention are drawn to additional embodiments which use alternate local oscillator duty cycles and phases to represent I and O magnitude and sign.

Additional advantages and novel features of the invention are set forth in part in the description which follows, and in part will become apparent to those skilled in the art upon examination of the following or may be learned by practice of the invention. The advantages of the invention may be realized and attained by means of the instrumentalities and combinations particularly pointed out in the appended claims.

### BRIEF SUMMARY OF THE DRAWINGS

The accompanying drawings, which are incorporated in and form a part of the specification, illustrate exemplary embodiments of the present invention and, together with the description, serve to explain the principles of the invention. In the drawings;

FIG. 1 shows a first conventional system and method to combine analog I and Q data for modulating a CMOS switching PA;

FIG. 2 is a general diagram illustrating the basis of conversion of I and Q data to sign and magnitude in accordance with aspects of the present invention;

FIG. 3 is a diagram illustrating the eight possible states of magnitude and sign of I and Q;

FIG. 4 illustrates the phase selection portion of a system in accordance with aspects of the present invention;

FIG. 5 shows a system provisioned in accordance with aspects of the present invention;

FIG. 6 illustrates the waveforms which represent the eight possible IQ states and which have been generated in accordance with aspects of the present invention; and

FIG. 7 is a further example embodiment of a phase selector.

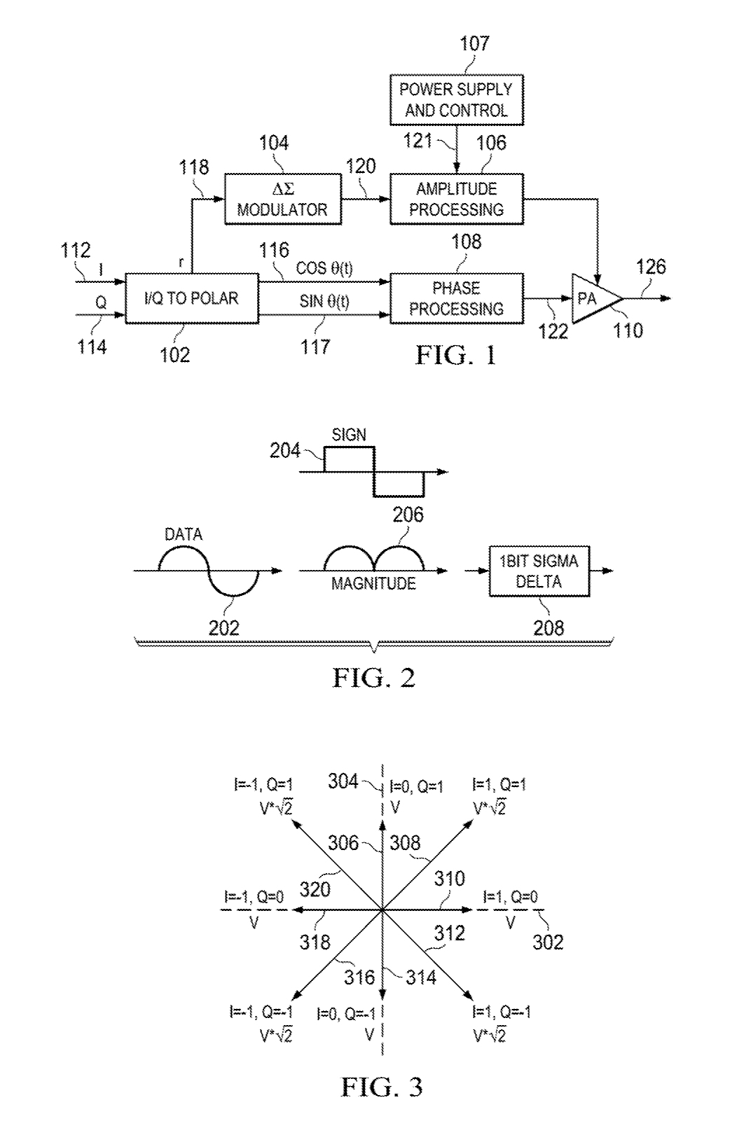

### DETAILED DESCRIPTION

A first aspect of the present invention is drawn to the provision of converters to convert IQ signals into I magnitude, I sign, Q magnitude and Q sign.

A second aspect of the invention, is drawn to the provision of an LO to provide a clock of period T, an I pulse generator and a Q pulse generator to generate four pulses of a certain duty cycle of the LO clock, the pulses' start times being T/4 apart, and art I phase selector and a Q phase selector to provide gating pulses based on the pulse generator outputs and the I sign and Q sign.

A third aspect of the invention is drawn to the provision of Boolean logic gates to gate the IQ amplitude data into the four T/4 time slots making up an LO cycle based on the phase selector outputs and to combine the amplitude data into a single bit stream.

A fourth aspect of the invention is drawn to the provision of a high-efficiency CMOS switch-mode PA to amplify the single bit stream and a matching and filter network to match to the network load, and to filter out-of-band noise.

It will be shown how a system and method in accordance with the aspects of the present invention provide a high efficiency PA solution by combining analog IQ phase and amplitude data into a single bit stream. A single bit stream allows the use of a simple single level PA. It will further be explained that such a system and method has a significant advantage over conventional systems and methods since it avoids the bandwidth widening, variable PA response performance limitations, multi-level PA requirement and I to Q leakage data corruption problems inherent in them.

The first aspect of the invention described above involves IQ data conversion concepts which will be explained with reference to FIG. 2.

FIG. 2 shows a diagram 200 that illustrates the basis of the conversion of IQ data to sign and magnitude in accordance with, aspects of the present invention.

As shown in the figure, diagram 200 includes waveform 202, waveform 204, waveform 206 and converter 208. Converter 208 is operable to perform delta sigma modulation on its analog input, thus producing digital pulses at its output.

Waveform 202 is an example waveform of an I or a Q signal to be processed in accordance with aspects of the present invention. Waveform 202 has portions both above and below zero magnitude and so contains both sign and magnitude. Sign is considered positive above zero and negative below zero. In operation in accordance with the present invention, waveform 202 is separated into sign and magnitude portions. Sign is illustrated by waveform 204, which is 1 (one) for as long as waveform 202 remains above zero, and −1 for as long as waveform 262 remains below zero. Sign extraction can be achieved by several possible conventional methods, a non-limiting example of which includes using IQ signals to drive a two position switch, the two positions representing positive and negative. Magnitude is illustrated by waveform 206 which shows that the magnitude is always zero or positive irrespective of sign. Magnitude extraction can be achieved by one of several conventional methods, for example using full-wave rectification. Waveform 204 can be considered “digitized” since it is already a waveform that changes between two states. Waveform 206, however, still contains analog variations and so needs digitization, performed, as illustrated, by converter 208. In operation, converter 208 is a 1-bit delta-sigma modulator that converts an analog magnitude signal into a 1-bit digital data stream. Alternatively 202 can also be a digital stream of data bits.

FIG. 3 is a polar diagram, diagram 300, illustrating the eight possible states of magnitude and sign of I and Q.

As shown in the figure, diagram 300 includes an x axis 302, a y-axis 304, a vector 306, a vector 308, a vector 310, a vector 312, a vector 314, a vector 316, a vector 318 and a vector 320.

X-axis 302 represents I magnitude and Y-axis 304 represents Q amplitude.

The vectors of diagram 300 are the eight possible combinations of states for I and Q shown on a constellation diagram. Moving clockwise, diagram 300 shows the eight vectors 306, 308, 310, 312, 314, 316, 318 and 320 which have polar angles 0°, 45°, 90°, 135°, 180°, 225°, 270° and 315° respectively. Vector 306 represents the state I=Q, Q=1. With amplitude ν. Vector 308 represents the state i=1, Q=1 with amplitude ν√2. Vector 310 represents the state I=1, Q=0 with amplitude ν. Vector 312 represents the state I=1, Q=1 with amplitude ν√2. Vector 314 represents the state I=0, Q=1 with amplitude ν. Vector 316 represents I=1, Q=1 with amplitude ν√2. Vector 318 represents the state I=1, Q=0 with amplitude ν. Vector 320 represents the state I=1, Q=1 with amplitude ν√2.

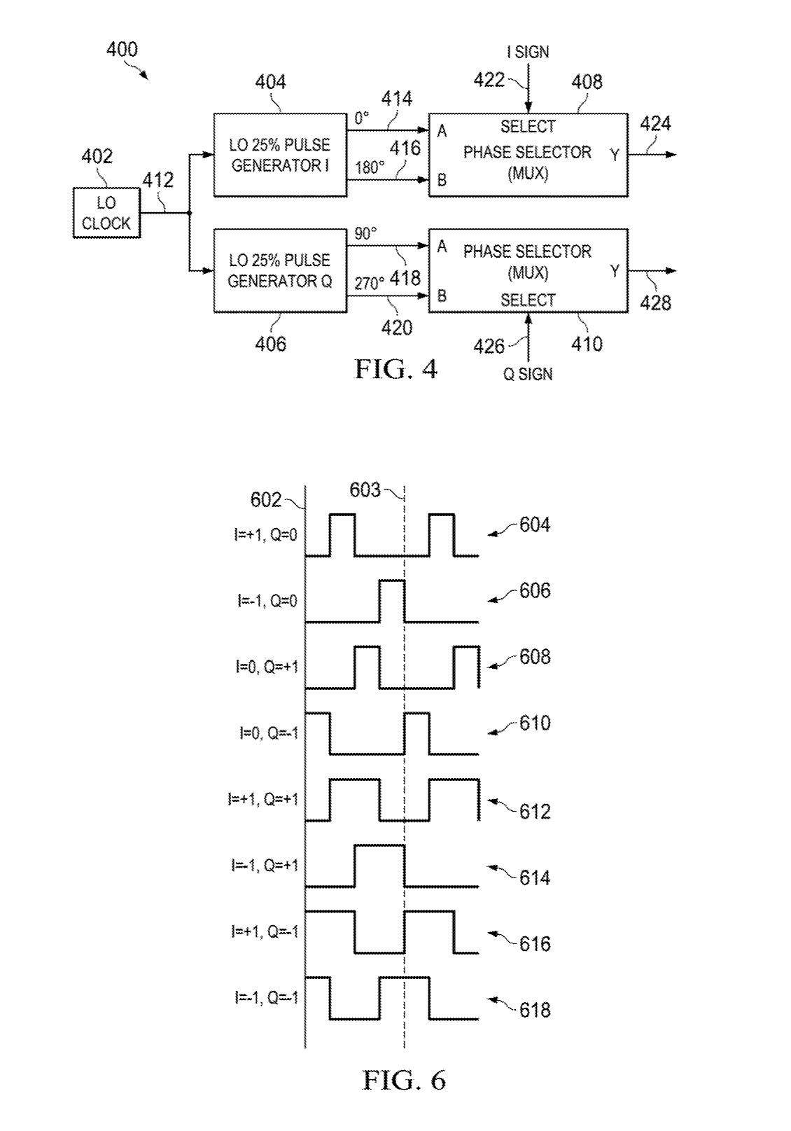

FIG. 4 shows system 400 which illustrates the phase selection portion of a system in accordance with aspects of the present invention.

FIG. 4 includes an LO clock 402, a pulse generator 404, a pulse generator 406, a phase selector 408 and a phase selector 410.

LO clock 402 is arranged to output a clock signal 412 to both pulse generator 404 and pulse generator 406, LO pulse generator 404 is arranged to output a signal 414 and a signal 416 to phase selector 408 LO pulse generator 406 is arranged to output a signal 418 and a signal 420 to phase selector 410. Phase selector 408 is arranged to input an I sign signal 424 and to output a signal 424, while phase selector 410 is arranged to input a Q sign signal 422 and to output a signal 428. Alternatively the blocks 404 and 406 can be replaced by a frequency divider, whose input clock is at twice the LO frequency and outputs four phases at the LO frequency with the phase relationships as described above between 414, 416, 418 and 420.

LO clock 402 generates a digital clock with period T. LO pulse generator 404 provides pulses of width T/4. LO pulse generator 406 also provides pulses of width T/4. Phase selector 408 provides an A/B multiplexing function based on its Select input. Phase selector 410 also provides an A/B multiplexing function based on its Select input.

In operation, the primary function of system 400 is to provide gating pulses that ultimately will allow amplitude data to appear at different portions of a local oscillator clock cycle depending upon whether the data is I, Q, positive, sign, negative sign or zero, in this way, the eight possible states of FIG. 3 are coded into a single data stream.

LO clock 412 provides the same clock, clock signal 412, to both LO pulse generators 404 and 406. From clock signal 412, pulse generator 404 then generates a 0° pulse (signal 414), i.e. a ¼ wave wide pulse occupying the first ¼ wave period of the LO cycle. Pulse generator 404 also generates a 180° pulse (signal 416), i.e. a ¼ wave wide pulse occupying the third ¼ wave period of the LO cycle. Similarly, pulse generator 406 then generates a 90° pulse (signal 418), i.e. a ¼ wave wide pulse occupying the second ¼ wave period of the LO cycle as well as a 180° pulse (signal 420), i.e. a ¼ wave wide pulse occupying the fourth and last ¼ wave of the LO cycle. Depending on the state of I sign, signal 422, which appears at the “select” input of phase selector 408, either the 0° pulse or the 180° pulse will appear at the output (signal 424). Similarly, depending on the state of Q sign, signal 426, which appears at the “select” input of phase selector 410, either the 90° pulse or the 270° pulse will appear at the output (signal 426). Signal 424 and signal 426 thus provide gating pulses which allow IQ amplitude data to be multiplexed into T/4 wide slots to form a single data stream. This is now described using a figure.

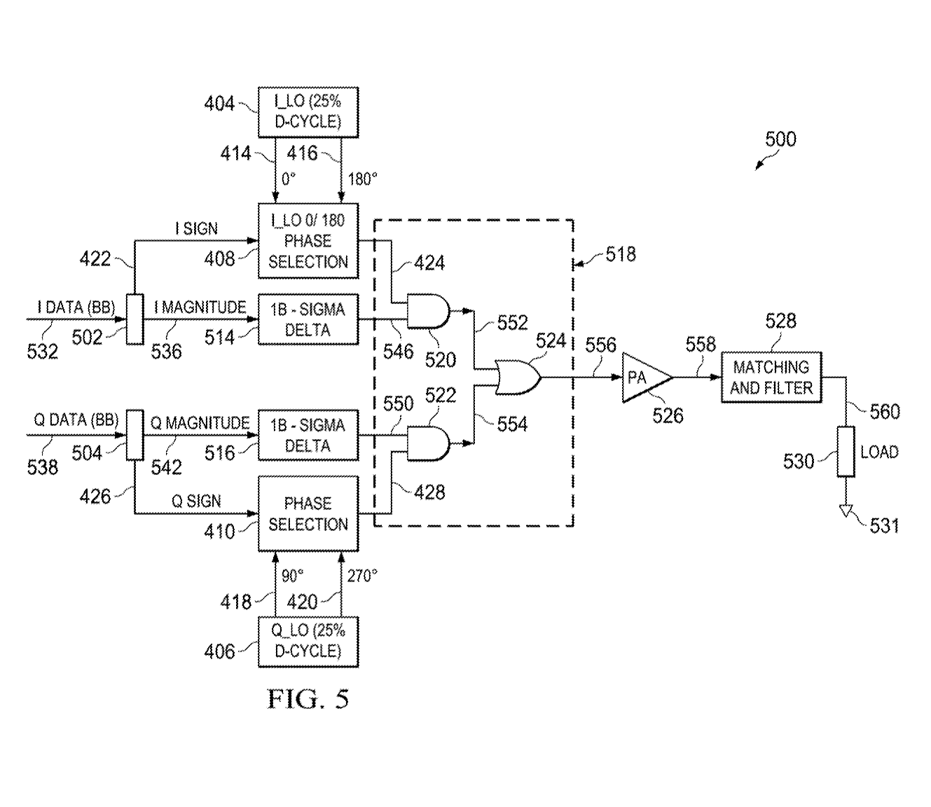

FIG. 5 shows system 500, a system provisioned in accordance with aspects of the present invention.

As shown in the figure, system 500 includes a converter 502, a converter 504, LO pulse generator 404, LO pulse generator 406, phase selector 408, phase selector 410, a delta-sigma modulator 514, a delta-sigma modulator 516, a logic component 518, a PA 526, a matching and filter component 528, a load 530 and a ground 531. Logic component 518 includes an AND gate 520, an AND gate 522 and an OR gate 524.

In this example, converter 562, convener 504, LO pulse generator 404, LO pulse generator 406, phase selector 408, phase selector 410, delta-sigma modulator 514, delta-sigma modulator 516, logic component 518, PA 526, matching and filter component 528, AND gate 520, AND gate 522 and OR gate 524 are distinct components. However, in other examples., at least two of converter 502, convener 504, LO pulse generator 404, LO pulse generator 406, phase selector 408, phase selector 410, delta-sigma modulator 514, delta-sigma modulator 516, logic component 518, PA 526, matching and filter component 528, AND gate 520, AND gate 522 and OR gate 524 may be combined as a unitary component. Further, in some examples, at least one of converter 502, converter 504, LO pulse generator 404, LO pulse generator 406, phase selector 408, phase selector 410, delta-sigma modulator 514, delta-sigma modulator 516, logic component 518, PA 526, matching and filter component 528, AND gate 520, AND gate 522 and OR gate 524 may be implemented as non-transient, tangible computer-readable media for carrying or having computer-executable instructions or data structures stored thereon. Such non-transient, tangible computer-readable media can be any available media that can be accessed by a general purpose or special purpose computer. Non-limiting examples of non-transient, tangible computer-readable media include physical storage and/or memory media such as RAM ROM, EEPROM, CD-ROM or other optical disk storage, magnetic disk storage or other magnetic storage devices, or any other medium which can be used to carry or store desired program code means in the form of computer-executable instructions or data structures and which can be accessed by a general purpose or special purpose computer. When information is transferred or provided over a network or another communications connection (hardwired and/or wireless, or a combination of hardwired or wireless) to a computer, the computer properly views the connection as a non-transient, tangible computer-readable media computer-medium. Thus, any such connection is properly termed a non-transient, tangible computer-readable medium. Combinations of the above should also he included within the scope of non-transient, tangible computer-readable media.

Converter 502 is arranged between a line 532, line 422 and a line 536. Converter 504 is arranged between a line 538, line 426 and a line 542. Phase selector 408 is arranged to input signals 414, 416 and 422 and to output signals 424. Delta-sigma modulator 514 inputs signals on line 536 and outputs signals on a line 546. Phase selector 410 is arranged to input signals 418, 420 and 426 and to output signal 428. Delta-sigma modulator 516 inputs signals on line 542 and outputs signals on a line 550, AND gate 520 inputs signal 424 from phase selector 408, inputs a signal from delta-sigma modulator 514 on a line 546, and outputs on a line 552, AND gate 522 inputs signal 428 from phase selector 410, inputs a signal from delta-sigma modulator 516 line 550, and outputs on a line 554, OR gate 524 is arranged to input signals via line 552 and line 554 and to output to PA 526 via a line 556. PA 526 outputs on a line 558 to matching and filter component 528. Load 530 is arranged between a line 560 from matching component 528 and ground 531. Matching and filter component 528 is arranged between PA 526 and load 530.

Converter 502 and converter 504 each convert an analog/digital Cartesian data signal into sign and magnitude data signals, LO pulse generator 404, LO pulse generator 406, phase selector 408, phase selector 410 are operable as described above with reference to FIG. 4. Delta-sigma modulator 514 and delta-sigma modulator 516 performs a 5-bit delta-sigma digitization. AND gate 520 and AND gate 522 perform a Boolean AND function, while OR gate 524 provides a Boolean OR function. PA 526 provides an amplified RF signal based on its input.

In operation, analog I and Q data are both split into sign and magnitude portions, as explained for FIG. 2, by converter 502 and converter 504, respectively. LO pulse generator 404, LO pulse generator 406, phase selector 408, phase selector 410 provide gating pulses as described above with reference to FIG. 4. I magnitude signals on line 536, which are analog signals, are converted to a digital stream by delta-sigma modulator 514, Similarly, Q magnitude signals on line 542 are converted to a digital stream by delta-sigma modulator 516.

AND gate 520 uses the gating pulses of signal 424, generated as described for FIG. 4, to place the I digital amplitude data appearing on line 546 into the first (0°) ¼ period portion of the LO cycle if I sign is positive, or into third (180°) ¼ period portion of the LO cycle if I sign is negative. Similarly, AMD gate 522 uses the gating pulses of signal 428 to place the Q digital amplitude data appearing on line 550 into the second (90°) ¼ period portion of the LO cycle, if Q sign is positive or into the fourth (270°) ¼ period, portion of the LO cycle, if Q sign is negative. The outputs of AND gate 520 and AND gate 522 are then combined using OR gate 524. Thus, there is a single data stream on line 556 to the power amplifier, PA 526, said data stream encoding I sign, I magnitude, Q sign and Q magnitude information. The waveforms representing the eight possible states if I and Q sign and magnitude appearing on line 556 and presented to PA 526 are further illustrated in FIG. 6 below. PA 526's output is then impedance matched to the network and to load 530 by matching and fitter component 528. Matching and filter component 528 also filters out the quantization noise generated by the delta-sigma conversion processes.

FIG. 6 is a timing diagram 600, illustrating the waveforms which represent the eight states shown in FIG. 3 and which are generated in accordance with aspects of the present invention as described for FIG. 5.

As shown in the figure, timing diagram 600 includes a line 602, line 603, a waveform 604, a waveform 606, a waveform 608, a waveform 610, a waveform 612, a waveform 614, a waveform 616 and a waveform 618.

Line 602 is the origin. Line 603 is the end of the first LO cycle and the start of a new cycle. Waveform 604 represents the state I=+1, Q<0; waveform 606 represents the state I=−1, Q<0; waveform 608 represents the state I=0, Q=+1; waveform 610 represents the state I=0, Q=−1; waveform 612 represents the state I=+1, Q=+1; waveform 614 represents the state I=−1, Q=+1; waveform 616 represents the state I=+1, Q=−1 and waveform 618 represents the state I=−1, Q=−1.

Each waveform, as illustrated, spreads across the four consecutive ¼ cycles (T/4) of the LO frequency. As each of the eight possible IQ states is unique, so is each of the eight waveforms. In a method described above using FIG. 3 through FIG. 5, a data stream, consisting of concatenated examples of these waveforms, combines all the I and Q sign and amplitude information present in the analog I and Q data input to the system as a single-bit data stream for amplification by a CMOS switch-mode PA.

The example embodiment described with reference to FIGS. 4-5 uses multiplexers and the generation of 25% duty cycle (¼ period) LO pulses for phase selection based on sign. The order of amplitude data for the four ¼ period slots within a LO clock period for this embodiment is I sign positive, Q sign positive, I sign negative, Q sign negative. This is not intended to he limiting since other embodiments can also be used to combine analog IQ data into a single bit stream by apportioning amplitude data into portions of an LO clock cycle based on sign. Another example embodiment may use, for instance, the generation of 75% (¾ wave) LO pulses and the order of amplitude data within the LO clock period may be different. This is described using a figure.

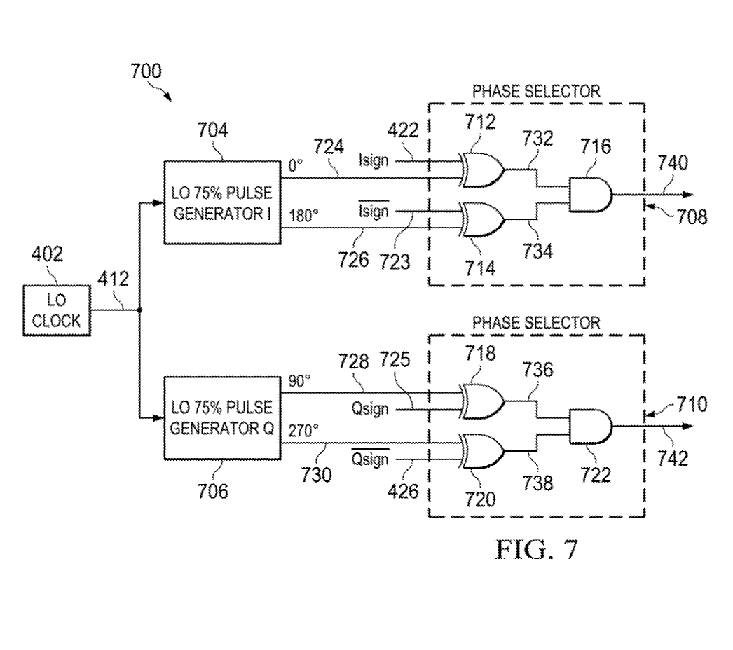

FIG. 7 shows system 700, an example embodiment using the generation of 75% LO duty cycle.

System 700 includes an LO clock 402, a pulse generator 704, a pulse generator 706, a phase selector 708 and a phase selector 710, Phase selector 708 includes an XOR gate 712, and XOR gate 714 and an AMD gate 716. Phase selector 710 includes an XOR gate 718, and XOR gate 720 and an AND gate 722.

In this example, LO clock 402, pulse generator 704, pulse generator 706, phase selector 708, phase selector 710, XOR gate 712, and XOR gate 714, AND gate 716, XOR gate 718, and XOR gate 720, AND gate 722 are distinct components. However, in other examples, at least two of LO clock 402, pulse generator 704, pulse generator 706, phase selector 708, phase selector 710, XOR gate 712, and XOR gate 714, AND gate 716, XOR gate 718, and XOR gate 720, AND gate 722 may be combined as a unitary component. Further, in some examples, at least, one of LO clock 402, pulse generator 704, pulse generator 706, phase selector 708, phase selector 710, XOR gate 712, and XOR gate 714, AND gate 716, XOR gate 718, and XOR gate 720, AND gate 722 may be implemented as non-transient, tangible computer-readable media for carrying or having computer-executable instructions or data structures stored thereon.

LO clock 402 is arranged to output a signal on line 412 to both pulse generator 704 and pulse generator 706. Pulse generator 704 is arranged to output signals on line a 724 and a line 726. Pulse generator 706 is arranged to output signals on line a 728 and a line 730. XOR gate 712 is arranged to input signals on a line 422 and line 724 and to output a signal to AND gate 716 on a line 732. XOR gate 714 is arranged to input signals on a line 723 and line 726 and to output a signal to AND gate 716 on a line 734, XOR gate 718 is arranged to input signals on a line 725 and line 728 and to output a signal to AND gate 722 on a line 736. XOR gate 720 is arranged to input signals on line 426 and line 730 and to output a signal to AND gate 722 on a line 738. AND gate 716 is arranged to input signals on line 732 and line 734 and to output a signal on line 740. AND gate 722 is arranged to input signals on line 736 and line 738 and to output a signal on line 742.

LO clock 402 generates a digital clock with, period T, LO pulse generator 704 generates 75% duty cycle pulses of width 3T/4. Pulse generator 706 also generates 75% duty cycle pulses of width 3T/4. Phase selector 708 and phase selector 710 both produce gating pulses based on sign. Both XOR gate 712 and XOR gate 714 provide a Boolean XOR function. AND gate 716 provides a Boolean AND function. Both XOR gate 718 and XOR gate 720 provide a Boolean XOR function. AND gate 722 provides a Boolean AND function.

In operation, system 700, while being a different embodiment, performs a similar function as system 400 in that amplitude data for I and Q is placed into separate ¼ wave periods within an LO clock cycle. In comparison with system 400 for FIG. 4, system 700 uses pulse generators (704 and 706) to generate pulses which are 3T/4 (75% of a cycle) wide and which are T/4 (¼ cycle) apart in time, i.e. starting at phase positions 0°, 90°, 180° and 270°. System 400 of FIG. 4, on the other hand, uses pulse generators which generate 174 wide pulses. The other difference is that the phase selectors of system 700 (708 and 710) employs XOR and AND logic gates to produce gating pulses instead of the multiplexers used in system 400 of FIG. 4. This results in a different order for gating of the amplitude data. For instance, while system 400 gating pulses for I sign positive, Q sign positive, I sign negative, Q sign negative get assigned to first, second, third and fourth ¼ cycle slots, respectively, as explained above for FIG. 4, gating pulses for system 700 for I sign positive, Q sign positive, I sign negative, Q sign negative get assigned to fourth, first, second and third ¼ period slots, respectively, for operation in accordance with aspects of the present invention, however, the order is not important as long as the amplitude data for I and O is placed into separate ¼ wave periods within an LO clock cycle depending oil sign.

It has been described, how a system and method, in accordance with aspects of the present invention can realize the high efficiency properties of a switch-mode CMOS PA by coding analog IQ signals into a single bit stream for amplification. It has been explained how the single bit stream, which represents all required properties of the analog IQ information, is generated by initially convening the analog IQ signals into digital I and Q sign and digital I and Q amplitude data and then using the sign information to arrange and order the amplitude information in time with respect to the cycles of a local oscillator.

It has been also been described that one conventional system and method is prone to problems with bandwidth widening and performance limitations due to variations in PA response. For a system and method in accordance with aspects of the present invention, the bandwidth widening problem is eliminated since the Cartesian to polar conversion processes are not employed. Furthermore, the performance limitations due to variations in PA response are also eliminated since there is no involvement of PA supply voltage for data encoding and no variations in supply bias causing variations in PA switching times. It has also been described that another conventional system and method has the problem that it requires a more complex multi-level power amplifier for operation and is also prone to I to Q leakage related data corruption problems, said corruption being due to the IQ combining being performed at the PA output followed by a post-PA filtering network, an arrangement which cannot achieve low settling times. For a system and method in accordance with aspects of the present invention, however, a multilevel PA is not required. Data corruption due to I to Q leakage is also not an issue since IQ combining is a fast digital process performed at the input of the PA.

A system and method in accordance with aspects of the present invention has therefore distinct and significant advantages over the prior art, said advantages being the elimination of many of the performance and complex implementation problems associated with the conventional systems and methods used to encode analog IQ information for use with efficient CMOS switch-mode PAs.

The foregoing description of various preferred embodiments of the invention have been presented for purposes of illustration and description. It is not intended to be exhaustive or to limit the invention to the precise forms disclosed, and obviously many modifications and variations are possible in light of the above teaching. The example embodiments, as described above, were chosen and described in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

1. A circuit comprising:
an I converter arranged to receive I data, to output I sign data based on the received I data and to output I magnitude data based on the received I data;
a Q converter arranged, to receive Q data, to output O sign data based on the received Q data and to output Q magnitude data based on the received Q data;
an I clock operable to generate an I phase based on the I sign data, the I phase having art I duty cycle;
a Q clock operable to generate a Q phase based on the O sign data, the Q phase having a Q duty cycle;
an I modulator operable to generate an I magnitude pulse stream based on the I magnitude data;
a Q modulator operable to generate a Q magnitude pulse stream based, on the Q magnitude data;
a digital logic component operable to generate an output signal based on tire I phase, the I magnitude pulse stream, the Q phase and the Q magnitude pulse stream; and
a power amplifier operable to generate an amplified signal based on the output signal.

2. The circuit of claim 1,
wherein said digital logic component comprises an I AND gate, a Q AND gate, and an OR gate,
wherein said I AND gate is operable to generate an I output based, on a Boolean AND of the I sign data and the I magnitude pulse stream,
wherein said Q AND gate is operable to generate a Q output based on a Boolean AND of the Q sign data and the Q magnitude pulse stream, and
wherein said OR gate is operable to generate an output signal based on a Boolean OR of the I output and the Q output.

3. The circuit of claim 2, wherein 25%≧I duty cycle≧0%.

4. The circuit of claim 3, wherein said I modulator comprises a delta-sigma modulator.

5. The circuit of claim 2, wherein said I modulator comprises a delta-sigma modulator.

6. The circuit of claim 1, wherein said I modulator comprises a delta-sigma modulator.

7. The circuit of claim 1, wherein said digital logic component comprises an I XOR gate, a Q XOR gate, and an OR gate.

8. The circuit of claim 7, wherein 100%>I duty cycle≧50%.

9. The circuit of claim 8, wherein said I modulator comprises a delta-sigma modulator.

10. The circuit of claim 7, wherein said I modulator comprises a delta-sigma modulator.

11. A method comprising;
receiving, via an I converter, I data;
outputting, via the I converter, I sign data based on the received I data;
outputting, via the I converter, I magnitude data based on the received I data;
receiving, via a Q converter, Q data:
outputting, via the O converter, Q sign data based on the received Q data;
inputting, via the Q converter, O magnitude data based on the received Q data;
generating, via an I clock, as I phase based on the I sign data, the I phase having an I duty cycle;
generating, via a Q clock, a Q phase based on the Q sign data, the Q phase having a Q duty cycle;
generating, via an I modulator, an I magnitude pulse stream based on the I magnitude data;
generating, via a Q modulator, a Q magnitude pulse stream based on the Q magnitude data;
generating, via a digital logic component, an output signal based on the I phase, the I magnitude pulse stream, the Q phase and the Q magnitude pulse stream; and
generating, via a power amplifier, an amplified signal based on the output signal.

12. The method of claim 11, wherein said generating, via a digital logic component, an output signal comprises:
generating, via I AND gate, an I output based, on a Boolean AND of the I sign data and the I magnitude pulse stream;
generating, via a Q AND gate, a Q output based on a Boolean AND of the Q sign data and die Q magnitude pulse stream; and
generating, via an OR gate, an output signal based on a Boolean OR of the I output and the Q output.

13. The method of claim 12, wherein 25%≧I duty cycle>0%.

14. The method of claim 13, wherein said generating an I magnitude pulse stream comprises generating the I magnitude pulse stream via a delta-sigma modulator.

15. The method of claim 12, wherein said generating an I magnitude pulse stream comprises generating the I magnitude pulse stream via a delta-sigma modulator.

16. The method of claim 11, wherein said generating an I magnitude pulse stream comprises generating the I magnitude pulse stream via a delta-sigma modulator.

17. The method of claim 11, wherein said generating, via a digital logic component, an output signal comprises generating the output signal via an I XOR gate, a Q XOR gate, and an OR gate.

18. The method of claim 17, wherein 100%>I duty cycle≧50%.

19. The method of claim 18, wherein said generating an I magnitude pulse stream comprises generating the I magnitude pulse stream via a delta-sigma modulator.

20. A circuit having an I data receiving component operable to receive I data, a Q data receiving component operable to receive Q data, a digital logic component and a power amplifier, wherein the improvement comprises:
an I modulator;
a Q modulator;
said digital logic component, being operable to output an output signal to said power amplifier, the output signal being based on a non-polar conversion of the received I data and a non-polar conversion of the received Q data,
said I data receiving component being operable to separate the I data into I sign data and I magnitude data,
said Q data receiving component being operable to separate the Q data into Q sign data and Q magnitude data,
said I modulator being operable to generate an I magnitude pulse stream based on the I magnitude data, and
said Q modulator being operable to generate a Q magnitude pulse stream based on the Q magnitude data.
